(19) United States
(12) Patent Application Publication
(10) Pub. No.: US 2026/0337028 A1
(43) Pub. Date: Oct. 29, 2026

(54) GRAPHITE SHEET, AND METHOD FOR PRODUCING SAME

(71) Applicant: Panasonic Intellectual Property Management Co., Ltd., Osaka (JP)

(72) Inventor: Fumitake ITOSE, Hokkaido (JP)

(21) Appl. No.: 19/103,762

(22) PCT Filed: Aug. 23, 2023
(86) PCT No.: PCT/JP2023/030358

§ 371 Date: Feb. 13, 2025

(30) Foreign Application Priority Data
Aug. 31, 2022 (JP) 2022-138768

(51) Int. Cl. C01B 32/205

(52) U.S. Cl. CPC C01B 32/205; C01P 2004/02; C01P 2004/32; C01P 2004/61; C01P 2006/32

(57) ABSTRACT

A graphite sheet includes a plurality of graphite layers.

### TECHNICAL FIELD

The present disclosure relates to graphite sheets and methods for producing the graphite sheets and specifically relates to a graphite sheet including a plurality of graphite layers and a method for producing the graphite sheet.

### BACKGROUND ART

Recently, electric vehicles, hybrid vehicles, and the like, which use an electric motor as their main or auxiliary drive source, have been put on the market in increasing numbers. In an inverter used to control their electric motor, for example, a power module, such as an insulated gate bipolar transistor (IGBT), generates a lot of heat. Therefore, such a heat generator is attached to a heat dissipator, such as a heat sink, to dissipate the heat generated during driving of, for example, the electric vehicles. In this case, smooth heat transmission from the heat generator to the heat dissipator uses a heat conductive sheet sandwiched between the heat generator and the heat dissipator, and as the heat conductive sheet, a graphite sheet is used.

Patent Literature 1 discloses a heat conductive sheet including a graphite sheet obtained by heat decomposition of an organic film. The graphite sheet has a region which is except for an end surface of the graphite sheet and whose plane direction is substantially perpendicular to the c-axis of each of graphene layers (graphite layers) included in the graphite sheet. The heat conductive sheet has a surface which is perpendicular to the c-axis of each graphene layer and which is exposed on the end surface of the graphite sheet.

In the graphite sheet obtained by the heat decomposition of the organic film as described in Patent Literature 1, however, most of the graphite layers are arranged in the plane direction, and therefore, the graphite sheet has a very high thermal conductivity of about 2000 W/mK in the plane direction, whereas the thermal conductivity in a thickness direction is as low as about 5 W/mK, that is, thermal resistance in the thickness direction is high.

### CITATION LIST

### Patent Literature

Patent Literature 1: JP 2013-222918 A

### SUMMARY OF INVENTION

It is an object of the present disclosure to provide a graphite sheet having reduced thermal resistance in a thickness direction and a method for producing the graphite sheet.

A graphite sheet according to an aspect of the present disclosure includes a plurality of graphite layers.

A method for producing graphite sheet according to an aspect of the present disclosure includes a first step, a second step, and a third step. The first step includes preparing a solution or a suspension, the solution or the suspension including graphene oxide and a surfactant. The second step includes forming a precursor film from the solution or the suspension. The third step includes subjecting the precursor film to heat treatment to obtain a graphite sheet including a plurality of graphite layers.

### BRIEF DESCRIPTION OF DRAWINGS

FIG. 1 is an electron micrograph of across section of a graphite sheet of Example 1; and

FIG. 2 is an electron micrograph of a cross section of a graphite sheet of Example 6.

### DESCRIPTION OF EMBODIMENTS

### 1. Overview

Graphite sheets in embodiments of the present disclosure and methods for producing the graphite sheets will be described below. Note that the embodiments described below are mere examples of various embodiments of the present disclosure. Various modifications may be made to the embodiments described below as long as the object of the present disclosure is achieved.

The graphite sheet is sandwiched, for example, between a heat generator and a heat dissipator, which are then fastened with, for example, screws, thereby compressing the graphite sheet to bring the graphite sheet in tight contact with the heat generator and the heat dissipator such that the graphite sheet is used as a heat conductive sheet that smoothly transmits heat generated from the heat generator to the heat dissipator. When the graphite sheet is produced by firing an organic film, most of graphite layers thus formed are arranged in a plane direction, and therefore, the graphite sheet has very low thermal resistance in the plane direction but has high thermal resistance in a thickness direction which is a thermal conduction direction when the graphite sheet is used as the heat conductive sheet.

To overcome this problem, the inventors conducted research on reducing the thermal resistance in the thickness direction by controlling the arrangement of the plurality of graphite layers formed in manufacturing the graphite sheet and found that employing a surfactant, or a surfactant and black lead particles, in manufacturing the graphite sheet can reduce the thermal resistance in the thickness direction. The inventors have thus accomplished the present disclosure.

A graphite sheet of a first embodiment of the present disclosure includes a plurality of graphite layers. A graphite sheet of a second embodiment of the present disclosure includes the plurality of graphite layers of the graphite sheet of the first embodiment and further includes a plurality of black lead particles between, and in at least part of, the graphite layers.

The graphite sheet of the present disclosure has reduced thermal resistance in the thickness direction. A reason why the graphite sheet according to the present disclosure and having the configuration described above provides the effect described above is not necessarily clear but is presumable as follows. That is, the presence of a surfactant in forming the graphite sheet presumably increases the proportion of graphite layers formed to be arranged in a direction having a component of a direction perpendicular to the plane direction to the graphite layers arranged in the plane direction. Regarding the action of the surfactant, for example, interaction between a raw material, such as graphene oxide, and the surfactant presumably leads to, for example, a change in the arrangement of the graphite layers to be formed. In addition, the surfactant is presumably decomposed by heat in heat treatment for forming the graphite sheet, and part, such as a residue, of the surfactant decomposed by the heat presumably contributes to binding of the graphite layers to each other. As a result, the graphite layers have increased number of parts coupled to each other in the thickness direction, which presumably reduces the thermal resistance in the thickness direction. Moreover, the presence of the black lead particles, in addition to the surfactant, in forming the graphite sheet presumably further increases the proportion of graphite layers arranged in directions other than the plane direction. Regarding the action of the black lead particle, for example, the presence of the black lead particles presumably causes, in proximity to the black lead particles, the graphite layers to be arranged in a direction having a component of a thickness direction. Consequently, reduced thermal resistance in the thickness direction of the graphite sheet can be achieved.

A method for producing the graphite sheet of the first embodiment of the present disclosure includes a first step, a second step, and a third step. The first step includes preparing a solution or a suspension, the solution or the suspension including graphene oxide and a surfactant. The second step includes forming a precursor film from the solution or the suspension. The third step includes subjecting the precursor film to heat treatment to obtain a graphite sheet including a plurality of graphite layers. In a method for producing the graphite sheet of the second embodiment of the present disclosure, the solution or the suspension in the first step of the method for producing the graphite sheet of the first embodiment further includes a plurality of black lead particles.

The method for producing the graphite sheet according to the present disclosure enables a graphite sheet having reduced thermal resistance in the thickness direction to be obtained by a simple method.

As described above, the present disclosure can provide a graphite sheet having reduced thermal resistance in the thickness direction and a method for producing the graphite sheet.

### 2. Details

### Graphite Sheet

### First Embodiment

The graphite sheet of the first embodiment (hereinafter also referred to as a graphite sheet (X)) includes the plurality of graphite layers (hereinafter also referred to as graphite layers (A)). That is, the graphite sheet (X) includes the plurality of graphite layers (A) stacked one on top of another in the thickness direction.

### (Graphite Layer)

The “graphite layer” refers to a layer of graphite (black lead) that forms a single cleaved surface. The graphite layer generally includes one or more graphene layers (a layer in which carbon atoms are arranged to form a hexagonal honeycomb lattice and which is generally a single layer).

The graphite layers (A) have an average thickness of, for example, greater than or equal to 0.001 μm and less than or equal to 20 μm, preferably greater than or equal to 0.01 μm and less than or equal to 10 μm.

The graphite layers (A) are formed preferably from graphene oxide, more preferably from the graphene oxide under the presence of the surfactant. Forming the graphite layers (A) from graphene oxide principally having a single layer structure and under the presence of the surfactant capable of interacting with oxygen-containing groups of the graphene oxide presumably further increases the proportion of graphite layers (A) arranged in the thickness direction of the graphite sheet (X) to be formed, consequently achieving further reduced thermal resistance in the thickness direction of the graphite sheet (X).

### Second Embodiment

A graphite sheet (X) of the second embodiment includes a plurality of graphite layers (A) and a plurality of black lead particles (hereinafter also referred to as black lead particles (B)). The plurality of black lead particles (B) are present between, and in at least part of, the graphite layers (A). That is, the graphite sheet (X) includes the plurality of black lead particles (B) between, and in at least part of, the plurality of graphite layers (A) stacked one on top of another in the thickness direction.

The graphite sheet (X) further includes the plurality of black lead particles (B), which presumably increases the proportion of graphite layers (A) arranged in a direction having a component of the thickness direction.

### (Graphite Layer)

The plurality of graphite layers (A) are similar to the plurality of graphite layers (A) in the first embodiment.

### (Black Lead Particle)

The black lead particles (B) mean particles of black lead. The “black lead” is one of allotropies of carbon and is also referred to as graphite. Note that the black lead particles (B) are different from the graphite layers (A).

Examples of the black lead include: natural black lead such as black lead stones and black lead minerals; and artificial black lead (synthetic black lead) such as high-orientation heat decomposition black lead and scale-shaped black lead. The black lead particles (B) preferably include particles of artificial black lead. In this case, further reduced thermal resistance in the thickness direction of the graphite sheet (X) can be achieved.

Examples of the shape of the black lead particles (B) include: a flat shape such as a scale-like flake shape, a scale-like shape, and a thin flake shape; and a spherical shape. The shape of the black lead particles (B) is preferably at least one of the spherical shape or the scale-like flake shape. In this case, further reduced thermal resistance in the thickness direction of the graphite sheet (X) can be achieved.

The plurality of black lead particles (B) preferably have an average particle diameter greater than or equal to 0.1 μm and less than or equal to 100 μm. The average particle diameter of the black lead particles (B) can be made fall within this range, thereby further reducing the thermal resistance. The average particle diameter of the black lead particles (B) is more preferably greater than or equal to 1 μm and less than or equal to 60 μm, much more preferably greater than or equal to 3 μm and less than or equal to 40 μm, particularly preferably greater than or equal to 10 μm and less than or equal to 30 μm. The average particle diameter of the black lead particles is a diameter at 50% in the cumulative distribution (D50) based on the volume of a plurality of (e.g., 100) black lead particles.

The average particle diameter of the plurality of black lead particles (B) is preferably greater than the average thickness of the graphite layers (A). Employing the plurality of black lead particles (B) having such an average particle diameter further increases the proportion of graphite layers (A) arranged in the direction having a component of the thickness direction, consequently achieving further reduced thermal resistance in the thickness direction of the graphite sheet (X).

At least part of the graphite layers (A) is preferably bound to at least some of the plurality of black lead particles (B). In this case, the black lead particles (B) are not discharged also when the graphite sheet (X) is cut, and the graphite sheet (X) has further reduced thermal resistance in the thickness direction. Examples of such a bonding include a covalent bonding of carbon atoms of the graphite layers (A) to carbon atoms of the plurality of black lead particles (B). Such a covalent bonding is presumably readily formed, for example, due to the action of part, such as a residue, of the surfactant decomposed by heat in heat treatment for forming the graphite sheet (X).

The distance between the plurality of graphite layers (A) is preferably shorter than the average particle diameter of the plurality of black lead particles (B). Moreover, the distance between the plurality of graphite layers (A) is preferably shorter than or equal to 25 μm. In such a case, the graphite layers (A) are arranged to avoid the black lead particles (B), and as a result, the graphite layers (A) are readily arranged in the thickness direction of the graphite sheet (X).

### First Embodiment, Second Embodiment

The average thickness of the graphite sheet (X) is, for example, greater than or equal to 1 μm and less than or equal to 150 μm, preferably greater than or equal to 10 μm and less than or equal to 120 μm, more preferably greater than or equal to 20 μm and less than or equal to 100 μm.

Part of the graphite layers (A) extends in the plane direction of the graphite sheet (X), and in the proximity to the plurality of black lead particles (B), at least part of the graphite layers (A) preferably extends in the thickness direction of the graphite sheet (X). The presence of the plurality of black lead particles (B) in forming the graphite sheet (X) presumably further increases the proportion of the graphite layers (A) arranged in the direction having a component of the thickness direction in the proximity to the plurality of black lead particles (B). Thus, including the graphite layers (A) which have components of the thickness direction and which are present to face an oblique direction efficiently achieves reduced thermal resistance in the thickness direction of the graphite sheet (X).

The compression ratio of the graphite sheet (X) when the graphite sheet (X) is compressed in the thickness direction at 200 kPa is preferably higher than or equal to 55%. Further increasing the compression ratio of the graphite sheet (X) enables the thermal resistance in the thickness direction to be further reduced. The compression ratio is more preferably higher than or equal to 60%, much more preferably higher than or equal to 65%. Moreover, the compression ratio is, for example, lower than or equal to 75%. Note that the compression ratio is the value (T0−T1)/T0 shown in percentage, where T0 is an initial thickness, and T1 is a thickness after a pressure of 200 kPa applied is removed.

The thermal resistance in the thickness direction of the graphite sheet (X) when the graphite sheet (X) is compressed in the thickness direction at 200 kPa is preferably less than or equal to 0.4 Kcm²/W. This enables the thermal resistance in the thickness direction of the graphite sheet (X) to be satisfactorily low. The thermal resistance in the thickness direction of the graphite sheet (X) is more preferably less than or equal to 0.27 Kcm²/W, much more preferably less than or equal to 0.24 Kcm²/W, particularly preferably less than or equal to 0.19 Kcm²/W. The lower the thermal resistance in the thickness direction of the graphite sheet (X), the more preferable. The lower limit of the thermal resistance is not limited to a particular value but is, for example, greater than or equal to 0.1 Kcm²/W.

### <Method for Producing Graphite Sheet>

A method for producing the graphite sheet of the present disclosure will be described below. The method for producing the graphite sheet of the present disclosure enables the graphite sheet (X) of the present disclosure having reduced thermal resistance in the thickness direction to be obtained by a simple method.

### First Embodiment

A method for producing the graphite sheet (X) of the first embodiment includes a first step, a second step, and a third step as described below. Each of these steps will be described below.

### (First Step)

The first step includes preparing a solution or a suspension, the solution or the suspension including graphene oxide and a surfactant.

The graphene oxide is graphene (principally including a compound having a structure in which carbon atoms are arranged to form a hexagonal honeycomb lattice) modified by oxygen-containing groups, such as carboxyl groups, carbonyl groups, and hydroxyl groups.

The surfactant refers to a substance which acts on a boundary surface of a substance to change the property of the substance. The surfactant generally has a structure including both hydrophilic and hydrophobic parts in a molecule.

Examples of the surfactant include: ionic surfactants such as anionic surfactants and cationic surfactants; and non-ionic surfactants. The surfactant includes preferably an ionic surfactant, more preferably an anionic surfactant. Employing such a surfactant can achieve further reduced thermal resistance in the thickness direction of the graphite sheet (X), which is to be obtained.

Examples of the anionic surfactant include: sulfonic acid or salts thereof; and carboxylic acid or salts thereof. Examples of the salts of the sulfonic acid and the salts of the carboxylic acid include: alkali metal salts such as lithium salts, sodium salts, and potassium salts; alkaline-earth metal salts such as magnesium salts, calcium salts, and barium salts; and amine salts such as triethanol amine salts, of the sulfonic acid and the carboxylic acid. Among these salts, the alkali metal salts are preferable, at least either one of the sodium salts or the potassium salts is more preferable, and the sodium salts are much more preferable.

Examples of the sulfonic acid include aliphatic sulfonic acid and aromatic sulfonic acid.

Examples of the aliphatic sulfonic acid include octanesulfonic acid and dodecylsulfonic acid. Examples of salts of the aliphatic sulfonic acid include octanesulfonic acid sodium salts and dodecylsulfonic acid sodium salts.

Examples of the aromatic sulfonic acid include: alkyl group-containing aromatic sulfonic acid, such as dodecylbenzene sulfonic acid; and alkyl group-free aromatic sulfonic acid, such as naphthalene trisulfonic acid. Examples of salts of the aromatic sulfonic acid include: salts of the alkyl group-containing aromatic sulfonic acid, such as sodium dodecylbenzenesulfonate; and salts of the alkyl group-free aromatic sulfonic acid, such as trisodium naphthalenetrisulfonate.

Examples of the carboxylic acid include tetradecanoic acid (myristic acid), hexadecanoic acid (palmitic acid), and octadecanoic acid (stearic acid). Examples of the salts of the carboxylic acid include sodium myristate, sodium palmitate, and sodium stearate.

The anionic surfactant includes preferably at least one selected from the group consisting of aliphatic sulfonic acids and salts thereof, and aromatic sulfonic acids and salts thereof, more preferably at least either one of the salts of the aliphatic sulfonic acids or the salts of the aromatic sulfonic acids. In this case, further reduced thermal resistance in the thickness direction of the graphite sheet (X), which is to be obtained, can be achieved more effectively.

The aliphatic sulfonic acids and the salts thereof include preferably the alkyl group-containing aromatic sulfonic acid and a salt thereof, more preferably the salt of the alkyl group-containing aromatic sulfonic acid. In this case, the surfactant includes alkyl groups that bind to an aromatic ring, and thus, further reduced thermal resistance in the thickness direction of the graphite sheet (X), which is to be obtained, can be achieved more effectively.

Examples of the alkyl group include: straight-chain alkyl groups such as n-octyl, n-dodecyl, n-tetradecyl, n-hexadecyl, n-octadecyl, and n-icosyl; and branched-chain alkyl groups such as isooctyl and isododecyl. The alkyl group is preferably the straight-chain alkyl group, more preferably the n-dodecyl group.

The length of a carbon chain of the alkyl group is preferably longer than or equal to 9 and shorter than or equal to 17. The carbon chain having a length of longer than or equal to 9 achieves further reduced thermal resistance of the graphite sheet (X). The carbon chain having a length of shorter than or equal to 17 enables graphene oxide dispersion to be further stabilized. The length of the carbon chain of the alkyl group is more preferably longer than or equal to 10 and shorter than or equal to 14, most preferably 12. The “length of the carbon chain of the alkyl group” refers to the number of carbons which the longest one of the carbon chains in the alkyl group has.

The solution or the suspension in the first step is prepared by, for example, adding an aqueous solution of graphene oxide to an aqueous solution of a surfactant to obtain a mixture, and agitating the mixture by using, for example, an agitating and defoaming device.

### (Second Step)

The second step includes forming a precursor film from the solution or the suspension prepared in the first step.

The precursor film in the second step can be formed by, for example, applying the solution or the suspension obtained in the first step to a base member such as PET by using a device such as a coater to have a prescribed thickness, and then, drying the solution or the suspension. The application thickness is, for example, greater than or equal to 0.1 mm and less than or equal to 3 mm. The drying temperature is, for example, higher than or equal to 30 °C and lower than or equal to 80 °C.

### (Third Step)

The third step includes subjecting the precursor film formed in the second step to heat treatment to obtain a graphite sheet (X) including a plurality of graphite layers (A).

The heat treatment in the third step can be performed by, for example, firing the precursor film formed in the second step. The firing is generally performed with a load applied to the precursor film. The firing temperature is, for example, higher than or equal to 2000 °C and lower than or equal to 3000 °C, preferably higher than or equal to 2500 °C and lower than or equal to 2800 °C.

Thus, the graphite sheet (X) including the plurality of graphite layers (A) can be obtained.

### Second Embodiment

A method for producing a graphite sheet of the second embodiment is similar to the method for producing the graphite sheet of the first embodiment except that the first step includes preparing a solution or a suspension, the solution or the suspension further including a plurality of black lead particles (B) in addition to the graphene oxide and the surfactant.

### (First Step)

The first step includes preparing the solution or the suspension including the graphene oxide, the surfactant, and the plurality of black lead particles (B). The graphene oxide and the surfactant are the same as those employed in the method for producing the graphite sheet of the first embodiment.

The plurality of black lead particles (B) each preferably have at least one of a spherical shape or a scale-like flake shape.

The plurality of black lead particles (B) preferably include particles of artificial graphite.

The plurality of black lead particles (B) preferably have an average particle diameter greater than or equal to 10 μm and less than or equal to 100 μm. Making the average particle diameter of the black lead particles (B) fall within this range presumably further increases, in the graphite sheet (X), the proportion of graphite layers (A) arranged in a direction having a component of the thickness direction, consequently achieving further reduced thermal resistance in the thickness direction of the graphite sheet (X). The average particle diameter of the black lead particles (B) is more preferably greater than or equal to 15 μm and less than or equal to 60 μm, much more preferably greater than or equal to 18 μm and less than or equal to 40 μm.

The ratio by weight of the plurality of black lead particles (B) to the total amount of the solid content of the graphene oxide and the plurality of black lead particles is preferably higher than or equal to 1% and lower than or equal to 70%. In this case, a robust graphite sheet (X) with a low compression ratio can be obtained. The ratio by weight is more preferably higher than or equal to 10% and lower than or equal to 60%, much more preferably higher than or equal to 25% and lower than or equal to 45%.

The graphite sheet (X) obtained in the third step preferably includes the plurality of black lead particles (B) between, and in at least part of, the graphite layers (A). Examples

The present disclosure will be more specifically described below with reference to examples, but the present disclosure should not be limited to the examples.

### <Manufacturing of Graphite Sheet>

A graphite sheet was manufactured by the following procedure.

### [First Step] (Preparation of Solution or Suspension)

### (Raw Material)

Raw materials employed for the preparation of the solution or the suspension will be described below.
Graphene oxide: graphene oxide aqueous dispersion (solid content concentration: 1.8 wt. %)
Black lead particle: MAG-4 (average particle diameter: 3.9 μm), SGS20 (average particle diameter: 20 μm), and G3 (average particle diameter: 38 μm) manufactured by Fuji Graphite Works Co., Ltd.

### Surfactant:

SDBS: sodium dodecylbenzenesulfonate
SDS: sodium dodecyl sulfonate
SO: sodium octanesulfonate
TNTS: trisodium naphthalenetrisulfonate

### Example 1

In a vial were put 0.45 g of powder of artificial graphite having an average particle diameter of 20 μm. To the powder, 12 g of aqueous solution (1.5 wt. %) of sodium dodecylbenzenesulfonate (SDBS) were added, and the powder and the aqueous solution were agitated to obtain a mixture. Then, 45 g of graphene oxide aqueous dispersion (1.8 wt. %) were added to the mixture, and the mixture was agitated by using an agitating and defoaming device, thereby preparing a solution or a suspension.

### Examples 2 to 5

Solutions or suspensions were prepared in a similar manner to Example 1 except that: powder of black lead particles having an average particle diameter shown in Table 1 below was used in the amount that results in the wt. % shown in Table 1; and types of surfactants shown in Table 1 were used in the amount that results in the wt. % shown in Table 1.

### Example 6

A solution or a suspension was prepared in a similar manner to Example 1 except that no black lead particles were added.

### Examples 7 to 9

Solutions or suspensions were prepared in a similar manner to Example 6 except that types of surfactants shown in Table 1 were used in the amount that results in the wt. % shown in Table 1.

### Comparative Example 1

In a vial, 45 g of graphene oxide aqueous dispersion (1.8 wt. %) were put and were agitated by using an agitating and defoaming device, thereby preparing a solution or a suspension.

### [Second Step] (Formation of Precursor Film)

### Examples 1 to 9 and Comparative Example 1

Each of the solution or the suspension obtained in the first step was applied to a PET base member by using a coater with a gap of 1.5 mm. Then, the solution or suspension was dried at 60 °C, thereby forming precursor films (raw material sheets before firing).

### [Third Step] (Obtaining Graphite Sheet by Heat Treatment)

### Examples 1 to 9 and Comparative Example 1

The precursor films formed in the second step were one-by-one sandwiched between graphite plates and were fired at 2700 °C with a load applied by the graphite plates having high density, thereby performing heat treatment to obtain a graphite sheet including a plurality of graphite layers.

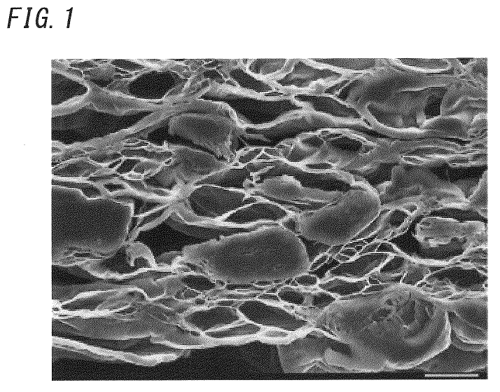

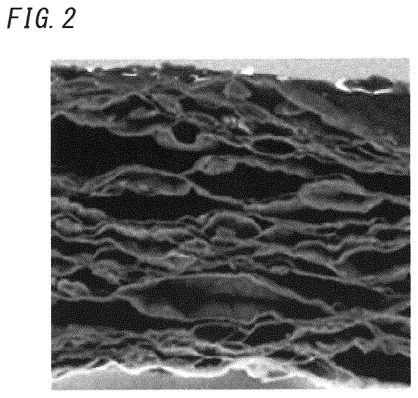

FIG. 1 shows an electron micrograph of a cross section of a graphite sheet of Example 1. FIG. 2 shows an electron micrograph of a cross section of a graphite sheet of Example 6. These electron micrographs show that the graphite sheets thus obtained include an increased proportion of graphite layers arranged in the direction having a component of the thickness direction. In particular, as shown in FIG. 1, the tendency that the graphite layers are arranged in such a direction increases in the proximity to the black lead particles.

### <Evaluation>

The graphite sheet thus obtained was evaluated in terms of the following criteria by the method described below. Evaluation results are shown in Table 1 below.

### [Thermal Resistance in Thickness Direction]

The thermal resistance of the graphite sheet compressed in the thickness direction at 200 kPa was measured by the following method (in accordance with ASTM D5470). The graphite sheet was sandwiched between two sheets of metal blocks such that the graphite sheet is under a pressure of 200 kPa applied in the thickness direction, and the thermal resistance from one of the metal blocks to the other of the metal blocks in a steady state was measured. The temperature of each metal block was measured by a thermocouple. The thermal resistance (Kcm²/W) was calculated based on Formula (1) below. Thermal resistance (Kcm²/W)=Temperature difference ΔT(K)×Surface area (cm²) of graphite sheet/Amount of passing heat (W) (1)

[Average Thickness after Compression]

The thickness of the graphite sheet under a pressure of 200 kPa applied in the thickness direction of the graphite sheet was measured at 10 points, and an arithmetic mean of the thicknesses was obtained as the average thickness (μm) after the compression.

### [Thermal Conductivity in Thickness Direction]

From the thermal resistance thus measured in the thickness direction and a measured value of the average thickness after the compression, the thermal conductivity in the thickness direction was calculated based on Formula (2) below.

Thermal conductivity (W/mK) in thickness direction=Average thickness (μm) after compression/(Thermal resistance (W/) in thickness direction×100) (2)

### [Material Thermal Conductivity]

Measurement was performed for the relationship between an applied pressure in the thickness direction and the thermal resistance in the thickness direction. The thermal resistance in the thickness direction was measured for each of six applied pressures, namely, 50 kPa, 100 kPa, 200 kPa, 300 kPa, 500 kPa, and 600 kPa. The measured value of the thermal resistance for each applied pressure was plotted to obtain the slope thereof, and the inverse number of the slope was used as the material thermal conductivity.

### [Exterior Appearance]

The exterior appearance of the graphite sheet was visually evaluated. When a crack was found, “crack” was noted in the Table.

TABLE 1

| | | Black Lead | | | | Thermal | Average | Thermal | | |
|---|---|---|---|---|---|---|---|---|---|---|
| | | Particles | | | | Resistance | Thickness | Conductivity | | |
| | | Average | | | | in Thickness | after Com- | in Thickness | | |
| | Graphene | Particle | | | | Direction | pression | Direction | Material | |
| | Oxide | Diameter | | Surfactant | | Kcm²/W | μm | W/mK | Thermal | Exterior |
| | (wt. %) | (μm) | (wt. %) | Type | (wt. %) | (200 kPa) | (200 kPa) | (200 kPa) | Conductivity | Appearance |
| Comparative | 1.8 | — | — | — | — | 0.285 | 25 | 0.88 | 1.80 | |
| Example 1 | | | | | | | | | | |
| Example 1 | 1.8 | 20 | 36 | SDBS | 14 | 0.13 | 30 | 2.31 | 2.70 | |
| Example 2 | 1.8 | 20 | 16 | SDBS | 14 | 0.123 | 30 | 2.44 | 3.41 | |
| Example 3 | 1.8 | 20 | 48 | SDBS | 14 | 0.174 | 41 | 2.36 | 1.8 | crack |
| Example 4 | 1.8 | 3.9 | 48 | SDBS | 14 | 0.231 | 33 | 1.43 | 1 | |
| Example 5 | 1.8 | 38 | 48 | SDBS | 14 | 0.27 | 27 | 1.00 | 0.6 | |
| Example 6 | 1.8 | — | — | SDBS | 14 | 0.16 | 21 | 1.31 | 2.7 | |
| Example 7 | 1.8 | — | — | SDS | 14 | 0.17 | 31 | 1.82 | 2.5 | |
| Example 8 | 1.8 | — | — | SO | 14 | 0.18 | 20 | 1.11 | 0.4 | |
| Example 9 | 1.8 | — | — | TNTS | 14 | 0.184 | 21 | 1.14 | 0.7 | crack |

The results in Table 1 show that the graphite sheets of Examples 6 to 9 (the first embodiment) and Examples 1 to 5 (the second embodiment) have reduced thermal resistance as compared with Comparative Example 1.

### SUMMARY

The embodiments and the examples which have been described above reveal that a graphite sheet (X) according to a first aspect of the present disclosure includes a plurality of graphite layers (A).

With the first aspect, reduced thermal resistance in a thickness direction of the graphite sheet (X) is achieved.

A second aspect of the present disclosure referring to the first aspect further includes a plurality of black lead particles (B) between, and in at least part of, the plurality of graphite layers (A).

According to the second aspect, containing the black lead particles while the structure of the plurality of graphite layers (A) is maintained presumably enables the proportion of the plurality of graphite layers (A) arranged in a direction having a component of the thickness direction to be further increased, and thus, further reduced thermal resistance in the thickness direction of the graphite sheet (X) is achieved.

In a third aspect of the present disclosure referring to the second aspect, the at least part of the plurality of graphite layers (A) is bound to at least some of the plurality of black lead particles (B).

According to the third aspect, the black lead particles (B) are not discharged even when the graphite sheet (X) is cut, and the graphite sheet (X) has further reduced thermal resistance in the thickness direction.

In a fourth aspect of the present disclosure referring to the second or third aspect, the plurality of black lead particles (B) have an average particle diameter greater than an average thickness of the plurality of graphite layers (A).

According to the fourth aspect, employing, as the black lead particles (B), black lead particles having an average particle diameter greater than the average thickness of the plurality of graphite layers (A) enables the proportion of the plurality of graphite layers (A) arranged in the direction having the component of the thickness direction to be further increased, consequently achieving further reduced thermal resistance in the thickness direction of the graphite sheet (X).

In a fifth aspect of the present disclosure referring to any one of the second to fourth aspects, part of the graphite layers (A) extends in the plane direction of the graphite sheet (X), and in the proximity to the plurality of black lead particles (B), at least part of the graphite layers (A) extends in the thickness direction of the graphite sheet (X).

According to the fifth aspect, the graphite layers (A) have components of the thickness direction of the graphite sheet (X) and are present to face an oblique direction in the proximity to the black lead particles (B), which efficiently achieves further reduced thermal resistance in the thickness direction of the graphite sheet (X).

In a sixth aspect of the present disclosure referring to any one of the first to fifth aspects, a compression ratio of the graphite sheet (X) when the graphite sheet (X) is compressed in the thickness direction at 200 kPa is higher than or equal to 55%.

According to the sixth aspect, further increasing the compression ratio of the graphite sheet (X) enables the thermal resistance in the thickness direction of the graphite sheet (X) to be further reduced.

In a seventh aspect of the present disclosure referring to any one of the first to sixth aspects, a thermal resistance in the thickness direction of the graphite sheet (X) when the graphite sheet (X) is compressed in the thickness direction at 200 kPa is greater than or equal to 0.1 Kcm²/W and less than or equal to 0.4 Kcm²/W.

The seventh aspect enables the thermal resistance in the thickness direction of the graphite sheet (X) to be satisfactorily low.

In an eighth aspect of the present disclosure referring to any one of the first to seventh aspects, the plurality of graphite layers (A) are formed from graphene oxide.

According to the eighth aspect, forming the plurality of graphite layers (A) from the graphene oxide achieves further reduced thermal resistance in the thickness direction of the graphite sheet (X).

A method for producing a graphite sheet (X) according to a ninth aspect of the present disclosure includes a first step, a second step, and a third step. The first step includes preparing a solution or a suspension, the solution or the suspension including graphene oxide and a surfactant. The second step includes forming a precursor film from the solution or the suspension. The third step includes subjecting the precursor film to heat treatment to obtain a graphite sheet (X) including a plurality of graphite layers (A).

The ninth aspect enables the graphite sheet (X) having reduced thermal resistance in the thickness direction to be obtained by a simple method.

In a tenth aspect of the present disclosure referring to the ninth aspect, the solution or the suspension in the first step further includes a plurality of black lead particles (B).

According to the tenth aspect, further containing the black lead particles (B) in the solution or the suspension achieves further reduced thermal resistance in the thickness direction of the graphite sheet (X), which is to be obtained.

In an eleventh aspect of the present disclosure referring to the tenth aspect, the graphite sheet (X) in the third step includes the plurality of black lead particles (B) between, and in at least part of, the plurality of graphite layers (A).

According to the eleventh aspect, containing the black lead particles (B) in the graphite sheet (X), which is to be obtained, presumably enables the proportion of the plurality of graphite layers (A) arranged in a direction having a component of the thickness direction to be further increased, which enables the thermal resistance in the thickness direction of the graphite sheet (X) to be further reduced.

In a twelfth aspect of the present disclosure referring to the tenth or eleventh aspect, the plurality of black lead particles (B) have at least one of a spherical shape or a scale-like flake shape.

According to the twelfth aspect, employing, as the black lead particles (B), black lead particles having the shape(s) described above achieves further reduced thermal resistance in the thickness direction of the graphite sheet (X), which is to be obtained.

In a thirteenth aspect of the present disclosure referring to any one of the tenth to twelfth aspects, the plurality of black lead particles (B) include particles of artificial graphite.

According to the thirteenth aspect, employing, as the black lead particles (B), the particles of the artificial graphite achieves further reduced thermal resistance in the thickness direction of the graphite sheet (X), which is to be obtained.

In a fourteenth aspect of the present disclosure referring to any one of the tenth to thirteenth aspects, the plurality of black lead particles (B) have an average particle diameter greater than or equal to 10 μm and less than or equal to 100 μm.

According to the fourteenth aspect, employing, as the black lead particles (B), black lead particles having an average particle diameter within the range described above presumably further increases the proportion of graphite layers (A) arranged in a direction having a component of the thickness direction, consequently achieving further reduced thermal resistance of the graphite sheet (X), which is to be obtained.

In a fifteenth aspect of the present disclosure referring to anyone of the ninth to fourteenth aspects, the surfactant includes an anionic surfactant.

According to the fifteenth aspect, employing an anionic surfactant as the surfactant more effectively achieves further reduced thermal resistance in the thickness direction of the graphite sheet (X), which is to be obtained.

In a sixteenth aspect of the present disclosure referring to the fifteenth aspect, the anionic surfactant includes at least one selected from the group consisting of aliphatic sulfonic acids and salts thereof, and aromatic sulfonic acids and salts thereof.

According to the sixteenth aspect, employing, as the anionic surfactant, the sulfonic acid or the salt thereof more effectively achieves further reduced thermal resistance of the graphite sheet (X), which is to be obtained.

In a seventeenth aspect of the present disclosure referring to the sixteenth aspect, the aromatic sulfonic acids and the salts thereof include alkyl group-containing aromatic sulfonic acid and salts thereof.

According to the seventeenth aspect, employing, as the aromatic sulfonic acid and the salt thereof, the aromatic sulfonic acid containing alkyl groups which bind to an aromatic ring more effectively achieves further reduced thermal resistance of the graphite sheet (X), which is to be obtained.

In an eighteenth aspect of the present disclosure referring to any one of the tenth to seventeenth aspects, in the solution or the suspension in the first step, a ratio by weight of the plurality of black lead particles (B) to a total amount of a solid content of the graphene oxide and the plurality of black lead particles (B) is higher than or equal to 1% and lower than or equal to 70%.

According to the eighteenth aspect, making the ratio of the black lead particles (B) to the total of the graphene oxide and the black lead particles (B) fall within the range described above enables a robust graphite sheet (X) having a low compression ratio to be provided.

1. A graphite sheet comprising a plurality of graphite layers.

2. The graphite sheet of claim 1, further comprising a plurality of black lead particles between, and in at least part of, the plurality of graphite layers.

3. The graphite sheet of claim 2, wherein
the at least part of the plurality of graphite layers is bound to at least some of the plurality of black lead particles.

4. The graphite sheet of claim 2, wherein
the plurality of black lead particles have an average particle diameter greater than an average thickness of the plurality of graphite layers.

5. The graphite sheet of claim 2, wherein
part of the plurality of graphite layers extends in a plane direction of the graphite sheet, and
in a proximity to the plurality of black lead particles, at least part of the plurality of graphite layers extends in a thickness direction of the graphite sheet.

6. The graphite sheet of claim 1, wherein
a compression ratio of the graphite sheet when the graphite sheet is compressed at 200 kPa in the thickness direction is higher than or equal to 55%.

7. The graphite sheet of claim 1, wherein
a thermal resistance in the thickness direction of the graphite sheet when the graphite sheet is compressed at 200 kPa in the thickness direction is greater than or equal to 0.1 Kcm²/W and less than or equal to 0.4 Kcm²/W.

8. The graphite sheet of claim 1, wherein
the plurality of graphite layers are formed from graphene oxide.

9. A method for producing a graphite sheet, the method comprising:
a first step of preparing a solution or a suspension, the solution or the suspension including graphene oxide and a surfactant;
a second step of forming a precursor film from the solution or the suspension; and
a third step of subjecting the precursor film to heat treatment to obtain a graphite sheet including a plurality of graphite layers.

10. The method of claim 9, wherein
the solution or the suspension in the first step further includes a plurality of black lead particles.

11. The method of claim 10, wherein
the graphite sheet in the third step includes the plurality of black lead particles between, and in at least part of, the plurality of graphite layers.

12. The method of claim 10, wherein
the plurality of black lead particles have at least one of a spherical shape or a scale-like flake shape.

13. The method of claim 10, wherein
the plurality of black lead particles include particles of artificial graphite.

14. The method of claim 10, wherein
the plurality of black lead particles have an average particle diameter greater than or equal to 10 μm and less than or equal to 100 μm.

15. The method of claim 9, wherein
the surfactant includes an anionic surfactant.

16. The method of claim 15, wherein
the anionic surfactant includes at least one selected from the group consisting of aliphatic sulfonic acids and salts thereof, and aromatic sulfonic acids and salts thereof.

17. The method of claim 16, wherein
the aromatic sulfonic acids and the salts thereof include alkyl group-containing aromatic sulfonic acid and a salt thereof.

18. The method of claim 10, wherein
in the solution or the suspension in the first step, a ratio by weight of the plurality of black lead particles to a total amount of a solid content of the graphene oxide and the plurality of black lead particles is higher than or equal to 1% and lower than or equal to 70%.
